(19) United States
(12) Patent Application Publication
(10) Pub. No.: US 2025/0298328 A1
(43) Pub. Date: Sep. 25, 2025

(54) CABLE SLAB, POSITIONING MODULE AND LITHOGRAPHIC APPARATUS

(71) Applicant: ASML Netherlands B.V., Veldhoven (NL)

(72) Inventors: Vincentius Fransiscus CLOOSTERMAN, Eindhoven (NL); Martinus Agnes Willem CUIJPERS, Veldhoven (NL); Gerard Johannes Pieter NIJSSE, Best (NL)

(73) Assignee: ASML Netherlands B.V., Veldhoven (NL)

(21) Appl. No.: 18/869,304

(22) PCT Filed: May 4, 2023
(86) PCT No.: PCT/EP2023/061867

§ 371 Date: Nov. 26, 2024

(30) Foreign Application Priority Data
May 30, 2022 (EP) 22176118.2

(51) Int. Cl. G03F 7/00; H02G 11/00

(52) U.S. Cl. CPC G03F 7/70991; H02G 11/00

(57) ABSTRACT

There is provided a cable slab for connecting a first movable object with a second object, the cable slab comprises a first permanent magnet having a first magnetic field orientation, the cable slab is arranged to be at least partially supported by a support comprising a second magnet having a second magnetic field orientation such that the first permanent magnet and the second magnet are repulsing when the first permanent magnet and the second magnet are facing each other to exert a force on cable slab, and the cable slab comprises one or more clamp brackets, each clamping one or more supply hoses and/or supply cables, the first permanent magnet is arranged in or on one of the one or more clamp brackets.

### CROSS-REFERENCE TO RELATED APPLICATION

The application claims priority of EP application Ser. No. 22/176,118.2 which was filed on 30 May 2022 and which is incorporated herein in its entirety by reference.

### FIELD

The present invention relates to a cable slab and a positioning module comprising such cable slab. The invention further relates to a lithographic apparatus comprising a positioning module.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

A lithographic apparatus comprises movable objects that need supplies. These supplies for example comprise, fluids, for example cooling fluid or a vacuum, electricity, such as power supply or control and measurement signals and/or optical signals. To bring these supplies to the movable object, a flexible supply structure comprising supply hoses and/or supply cables may be provided to allow a flexible connection of the supply hoses and/or supply cables between the movable object and another object.

In an embodiment, the flexible supply structure may for example be a C-shaped cable slab comprising the supply hoses and/or supply cables which cable slab is at least partially supported on a support. The support may be a slide plate on which the supply hoses and/or supply cables are mechanically supported. Typically the C-shaped cable slab is orientated in a direction of movement of the movable object, i.e. the supply hoses and/or supply cables each extend in a plane extending in the main direction of movement of the movable object and the vertical direction. When the moveable object moves in the main direction of movement, the C-shaped cable slab may roll back and forth, wherein a smaller or larger part of the cable slab is supported by the support.

In some embodiments, the movable object is arranged to be movable in at least a first horizontal direction and the movable object is supported on a second movable object movable in a second horizontal direction. Accelerations of the second movable object in the second horizontal direction may result in inertial forces on the cable slab in the second horizontal direction. These inertial forces may result in sliding of the cable slab over the support surface of the support, which may lead to wear of the support surface, the supply hoses and/or the supply cables. This wear may have a substantial negative effect on the maximum life time of the supply hoses and/or supply cables. Moreover, particles that are released from the support surface, the supply hoses and/or the supply cables due to wear may cause substrate defects in the lithographic process.

### SUMMARY

It is an object of the invention to provide an improved flexible supply structure. In particular, it is an object of the invention to provide a flexible supply structure that is less susceptible to wear and/or wherein generation of particles due to wear of the flexible supply structure and/or its support is substantially reduced.

According to an aspect the invention there is provided a flexible supply structure, for example a cable slab, for connecting a first movable object with a second object,
wherein the flexible supply structure comprises a first permanent magnet having a first magnetic field orientation,
wherein the flexible supply structure is arranged to be at least partially supported by a support comprising a second magnet having a second magnetic field orientation such that the first permanent magnet and the second magnet are repulsing when the first permanent magnet and the second magnet are facing each other to exert a force, for example a lifting force, on the flexible supply structure, and
wherein the cable slab comprises one or more clamp brackets, each clamping one or more supply hoses and/or supply cables, wherein the first permanent magnet is arranged in or on one of the one or more clamp brackets.

According to an aspect the invention there is provided a positioning module comprising:
a first movable object;
a second object;
the flexible supply structure according to any of the clause 1-6, wherein a first end of the flexible supply structure is connected to the first object and a second end of the flexible supply structure is connected to the second object; and
a support, wherein the support comprises a second magnet having a second magnetic field orientation such that the first permanent magnet and the second magnet are repulsing when the first permanent magnet and the second magnet are facing each other to exert a force, for example a lifting force, on the flexible supply structure.

According to an aspect the invention there is provided a lithographic apparatus comprising the positioning module of any of the clause 7-15.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source;

FIG. 2 depicts a positioning module comprising a flexible supply structure according to an embodiment of the invention;

FIG. 3 depicts a side view of the flexible supply structure of FIG. 2;

FIG. 4 shows a cross section of a lower part of the flexible supply structure of FIG. 2;

FIGS. 5A-5C show different positions of the positioning module of FIG. 2; and

FIG. 6 shows a cross section of an alternative embodiment of a lower part of a flexible supply structure according to the invention.

### DETAILED DESCRIPTION

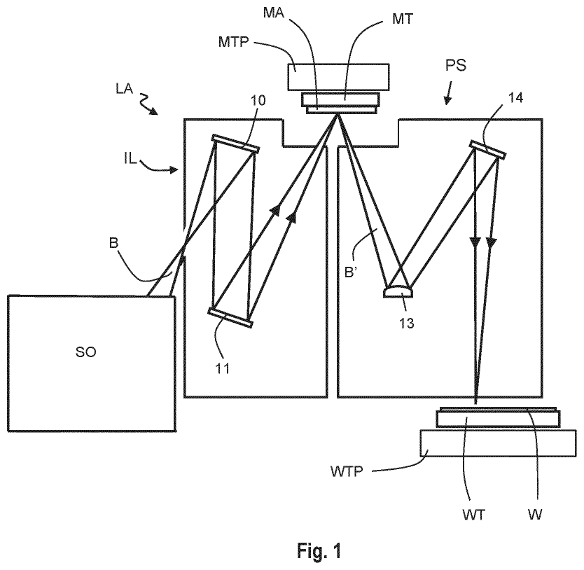

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

A substrate table positioning system WTP is provided to position the substrate table WT in a desired position. The substrate positioning system WTP comprises a position measurement system to measure a position of the substrate table WT and an actuation system to move the substrate table WT to a desired position. A patterning device support positioning system MTP is provided to position the support structure MT in a desired position. The patterning device support positioning system MTP also comprises a position measurement system to measure a position of the support structure MT and an actuation system to move the support structure MT to a desired position.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

The lithographic process comprises a series of projection phases, in which the patterned EUV radiation beam B′ is projected onto the substrate W (exposure phase) and/or in which the substrate W is being aligned with the patterned EUV radiation beam B′ (alignment phase) and idle phases in which no patterned EUV radiation beam B′ is projected onto the substrate W, or on a non-relevant part of the substrate W and positioning accuracy of the substrate W with respect to the patterned EUV radiation beam B′ is less critical. During the projection phase the patterning device and the substrate may be moved in a scanning movement with a constant scanning velocity. The idle phase may be used to decelerate and (re)accelerate the patterning device MT and the substrate W to the desired scanning velocity and a desired alignment with respect to the EUV radiation beam B and the patterned EUV radiation beam B′, respectively. The constant scanning velocity of the patterning device MT is typically different than the constant scanning velocity of the substrate W.

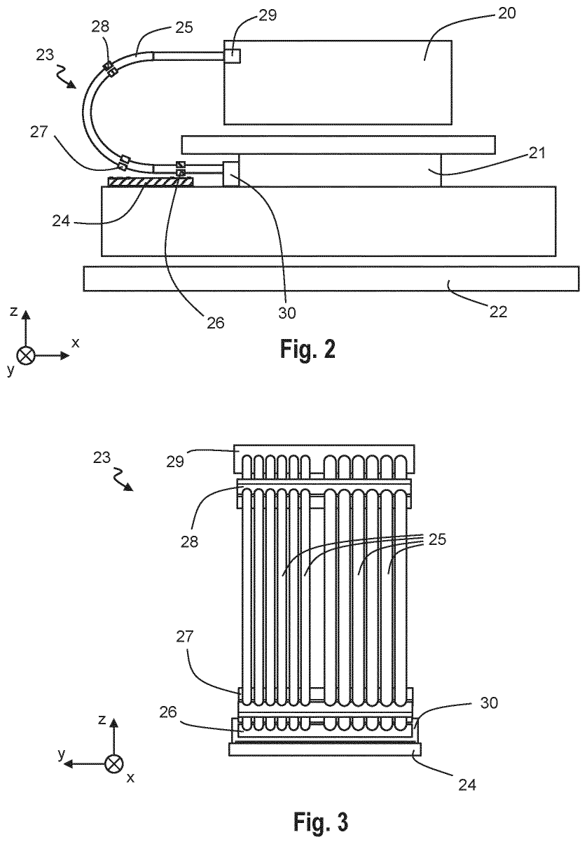

FIG. 2 shows a positioning module comprising a first movable object 20, a second movable object 21 and a base frame 22. The first movable object 20 is supported on the second movable object 21 and is movable with respect to the second movable object 21 in a first horizontal direction, e.g. the x-direction. The second movable object 21 is supported on the base frame 22 and is movable with respect to the base frame 22 in a second horizontal direction, e.g. the y-direction. Actuators may be provided to exert actuation forces on the first movable object 20 and the second movable object 21 to move the first movable object 20 and the second movable object 21 towards a desired position.

The positioning module may for example be part of a substrate positioning system WTP arranged to position a substrate in a desired position.

It may be desirable that supplies, for example fluids, such as cooling fluid or vacuum, electricity, such as electric power or electric measurement or control signals and light, such as optical signals, are exchanged between the first movable object 20 and the second movable object 21. The positioning module therefore comprises a flexible supply structure 23 that extends between the first movable object 20 and the second movable object 21 to exchange these supplies between the first movable object 20 and the second movable object 21. The flexible supply structure 23 is at least partially supported by a support 24.

FIG. 3 shows a side view of the flexible supply structure 23 and the support 24. The flexible supply structure 23 comprises multiple supply hoses and supply cables 25 between the first movable object 20 and the second movable object 21. The flexible supply structure 23 further comprises a first clamp bracket 26, a second clamp bracket 27, and a third clamp bracket 28 to clamp the supply hoses and/or supply cables 25 to form a cable slab. One end of the cable slab is connected to a first manifold 29 mounted on the first movable object 20 and a second opposite end of the cable slab is connected to a second manifold 30 mounted on the second movable object 21. The first manifold 29 and the second manifold 30 may be any structure or device arranged to connect the supply hoses and/or supply cables 25 to the first movable object 20 and the second movable object 21, respectively. The clamp brackets 26, 27, 28 each comprise a pair of clamp strips between which the multiple supply hoses and supply cables 25 are clamped next to each other.

The cable slab is shaped in a C-shape having a lower part, a middle part and an upper part. The C-shaped cable slab is orientated in the direction of movement of the first movable object 20, i.e. the supply hoses and/or supply cables 25 each extend in a plane extending in the x-direction and z-direction. When the first moveable object 20 moves in the main direction of movement, the C-shaped cable slab may roll back and forth, wherein a smaller or lager part of the cable slab is supported by the support.

A further flexible supply structure (not shown) similar to the flexible supply structure 23 between the first movable object 20 and the second movable object 21 may be provided between the second movable object 21 and the base frame 22 to exchange supplies between the second movable object 21 and the base frame 22. This further flexible supply structure will typically be orientated in the y-direction, i.e. the supply hoses and/or supply cables will extend in the plane extending in the y-direction and z-direction.

In prior art embodiments of a cable slab, the support may be formed as a slide plate on which the supply hoses and/or supply cables are mechanically supported. Inertia forces on the cable slab due to accelerations of the second movable object in the y-direction may result in sliding of the cable slab over the support surface of the slide plate. This sliding may lead to wear of the support surface, the supply hoses and/or the supply cables. The wear may have a substantial negative effect on the maximum life time of the supply hoses and/or supply cables. Moreover, particles that are released due to wear of the support surface, the supply hoses and/or the supply cables may lead to substrate defects in the lithographic process. Wear may also occur in cable slabs where there is no movement in transverse direction, for example in a cable slab arranged between a stationary support object and a movable object that linearly moves in one direction. This wear may for example be caused by imperfect alignment of the supply hoses and/or supply cables.

To prevent or reduce wear caused by mechanical contact between the support 24 and the flexible supply structure 23, the flexible supply structure 23 comprises multiple first permanent magnets having a first magnetic field orientation and the support 24 comprises multiple second magnets having a second magnetic field orientation. Each first permanent magnet is associated with a second magnet such that the first permanent magnet and the second magnet are repulsing when the first permanent magnet and the associated second magnet are facing each other in order to exert a lifting force on the flexible supply structure 23.

In the embodiment shown in FIG. 2, the first permanent magnets and the second magnets are designed to support the flexible supply structure 23 in a floating state, i.e. without direct mechanical contact between the flexible supply structure 23 and the support 24. In an alternative embodiment, there may still be direct mechanical contact between the flexible supply structure 23 and the support 24, but the lifting force exerted on the flexible supply structure 23 through the first permanent magnet and the second magnet may substantially reduce the pressure with which the flexible supply structure 23 is pressed on the support 24. As a result of this reduced pressure, the friction forces between the flexible supply structure 23 and the support 24 are also reduced which results in less wear of the contact surfaces between the flexible supply structure 23 and the support 24, such as contact surface of the support surface, the supply hoses and/or the supply cables 25.

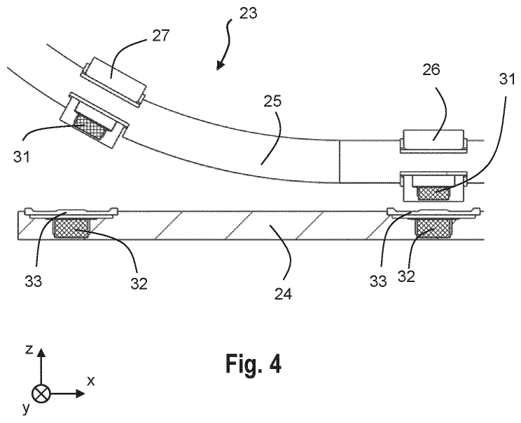

FIG. 4 shows a cross-section of the lower part of the C-shape of the flexible supply structure 23 with first clamp bracket 26 and second clamp bracket 27. In each of the first clamp bracket 26 and the second clamp bracket 27 a first permanent magnet 31 is arranged. Each first permanent magnet 31 is associated with a second permanent magnet 32 arranged in the support 24.

Each first permanent magnet 31 has a first magnetic field orientation, and each associated second permanent magnet 32 has a second magnetic field orientation such that the first permanent magnet 31 and the second permanent magnet 32 are repulsing when the first permanent magnet 31 and the second magnet 32 are facing each other to exert a lifting force on the flexible supply structure.

In the cross section shown in FIG. 4, two first permanent magnets 31 in the clamp brackets 26, 27 and two second permanent magnets 32 in the support 24 are shown. Distributed over the length direction of the clamp brackets 26, 27 and the support 24 (y-direction) multiple first permanent magnets 31 and multiple second permanent magnets 32 may be provided to obtain a suitable support over the whole width, in y-direction, of the flexible supply structure 23.

As discussed, the magnetic fields of the first permanent magnets 31 and the second permanent magnets 32 are selected such that the support 24 will support the flexible supply structure 23 in a floating manner, i.e. without direct mechanical contact between the flexible supply structure 23 and the support 24. As a safety measure, crash elements 33 are arranged in the support 24 that provide a safe surface in case one or both of the clamp brackets 26, 27 would inadvertently engage the support 24. The crash elements 33 may for example be made of clastic material capable of supporting the flexible support structure 23.

In the shown embodiment, a main axis of the first magnetic field orientation of the first permanent magnets 31 is arranged perpendicular to the tangent of the flexible supply structure at the location of the first permanent magnets 31 and a main axis of the second magnetic field orientation of the second permanent magnets 32 is arranged vertically. Other suitable magnetic field orientations of the first magnetic field and the second magnetic field may also be used.

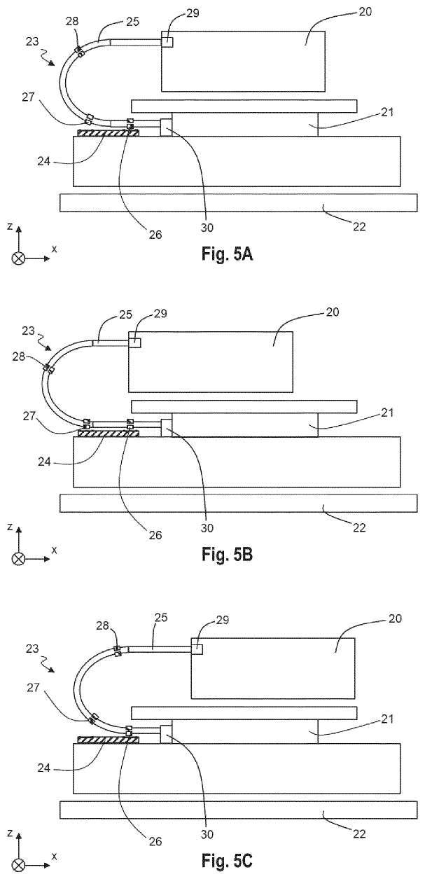

FIGS. 5A-5C show the positioning module of FIG. 2 having the first movable object 20 in different positions in x-direction.

FIG. 5A shows a position of the first movable object 20 substantially corresponding to the position in FIG. 2. It can be seen that the flexible supply structure 23 is supported by the support 24 in floating manner due to the magnetic upward forces between the first permanent magnets 31 and the second permanent magnets 32. In this position of the first movable object 20, the first clamp bracket 26 is closer to the support 24 than the second clamp bracket 27 resulting in a larger upwards magnetic force being exerted on the first clamp bracket 26 than on the second clamp bracket 27. The stiffness of the multiple supply hoses and supply cables 25 maintains the flexible supply structure in a C-shape.

In FIG. 5B, the first movable object 20 has been moved to the left. The C-shape is rolled to the left and the lower part of the C-shape is moved to a closer position to the support 24 such that the first clamp bracket 26 and the second clamp bracket 27 are at substantially the same distance from the support 24. Due to the magnetic forces between the first permanent magnets 31 and the second permanent magnets 32, the flexible supply structure 23 is still supported in a floating manner.

In FIG. 5C, the first movable object 20 is moved to the right compared with the position of FIG. 5A. Due to this position of the first movable object 20, the second clamp bracket 27 is moved further away from the support 23 resulting in a smaller upwards magnetic force being exerted on the second clamp bracket 27. The first clamp bracket 26 is still spaced from the support 24 and therewith the flexible support structure 23 is supported in a floating manner.

Since in all positions of the first movable object 20 in x-direction, the flexible support structure 23 has no direct mechanical contact with the support 24, wear of the flexible support structure 23, for example wear of the supply hoses and supply cables 25, due to friction between the flexible support structure 23 and the support 24 is prevented. This has a beneficial effect on the life time of the flexible support structure 23 and reduces the quantity of particles that are released due to wear.

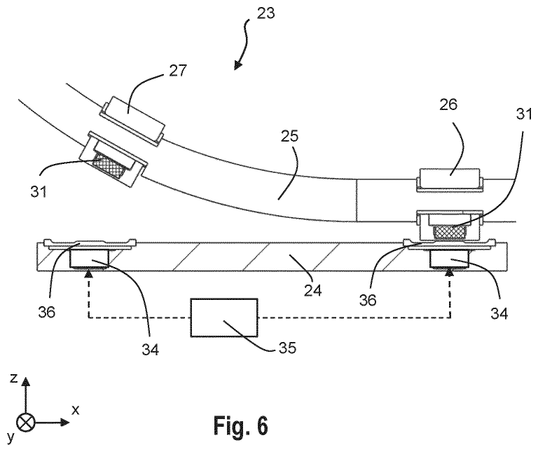

FIG. 6 shows an alternative embodiment of a lower part of the flexible supply structure 23. Corresponding to the embodiment of FIG. 2, the flexible supply structure 23 comprises a first clamp bracket 26 and a second clamp bracket 27, each comprising a pair of clamp strips between which the multiple supply hoses and supply cables 25 are clamped in a row. Also each of the clamp brackets 26, 27 comprises at least one permanent magnet 31.

The support 24 comprises second magnets 34, each second magnet 34 being associated with one of the first permanent magnets 31. The second magnets 34 are electromagnets having a second magnetic field that can be controlled by a magnetic field controller 35. The second magnetic field of the second magnet 34 associated with the first permanent magnet 31 in the first clamp bracket 26 may be controlled independently from the second magnetic field of the second magnet 34 associated with the first permanent magnet 31 in the second clamp bracket 27.

Each first permanent magnet 31 has a first magnetic field orientation, and each associated second magnet 34 has a second magnetic field orientation such that the first permanent magnet 31 and the second magnet 34, when magnetically activated by magnetic field controller 35, are repulsing when the first permanent magnet 31 and the second magnet 34 are facing each other in order to exert a lifting force on the flexible supply structure 23.

The support 24 is provided with support elements 36 to provide a suitable support surface for receiving the first clamp bracket 26 and the second clamp bracket 27. The support elements 36 may be made of elastic material, corresponding to the crash elements 33 of the embodiment of FIG. 4. As an alternative, the support elements 36 may be made of another material suitable to support the first clamp bracket 26 and the second clamp bracket 27, for example polyethylene or another relatively hard plastic material.

In the state shown in FIG. 6, there is direct mechanical contact between the first clamp bracket 26 and the associated support element 36 of the support 24. This position can be a rest position, in which the second magnet 34 is not magnetically activated by the magnetic field controller 35. This rest position may for example be used when the positioning module is not actively used.

The shown position can also be a position during movement of the first movable object 20 of the positioning module. The second magnets 34 may be activated to exert a magnetic force on the first permanent magnets 31 in order to create a lifting force on the flexible supply structure 23 that decreases the pressure with which the first clamp bracket 26 is pressed on the support element 36.

It is noted that in this embodiment, the flexible supply structure 23 is supported on the first clamp bracket 26 and/or the second clamp bracket 27 instead of on the supply hoses and supply cables 25 as usual in prior art embodiments.

Since the magnetic fields of the two second magnets 34 may be independently controlled, the magnetic forces exerted on the flexible supply structure 23 may be made dependent on the position of the flexible supply structure 23 and/or the first movable object 20 with respect to the associated support clement 36. For example, when a permanent magnet 31 is moving towards the second magnet 34, due to a movement of the first movable object 20 in left direction, the magnetic field of the second magnet 34 may be temporarily increased to decelerate the movement of the respective clamp bracket 26, 27 towards the support 24. This deceleration may for example be beneficial to prevent that the respective clamp bracket 26, 27 inadvertently hits the support element 36, when supporting the supply structure 23 in a floating manner, or to ensure a smooth landing on the support element 36 when mechanical contact between the support element 36 and the respective clamp bracket 26, 27 is allowed.

Hereinabove, a flexible supply structure 23 is shown and described having a C-shaped configuration, wherein a lower part of the C-shaped configuration is supported by a support, and wherein a magnetic force is used to exert a lifting force on the flexible supply structure 23, in particular the lower part thereof. In other embodiments, as an alternative of or in addition to the magnetic support at the lower part of the flexible supply structure 23, there may also be provided magnetic support for the middle part of the upper part of the C-shaped configuration. For example, the third clamp bracket 28 of FIG. 2 may comprise one or more further permanent magnets that cooperate with one or more further magnets in a support clement (not shown), such that the one or more further permanent magnets and the one or more further magnets are repulsing when the one or more further permanent magnets and the one or more further magnets are facing each other to exert a force, for example a lifting force, on the flexible supply structure.

It may also be possible that the flexible supply structure 23 has other shapes or configurations, wherein repulsing magnetic forces are used to exert a force on the flexible supply structure. The force exerted on the flexible supply structure 23 may be a lifting force in order to reduce or take away the pressure with which the flexible supply structure 23 is pressed on the support 24, or it may be another beneficial force, for example a force to influence the shape of the flexible supply structure 23. The force may be exerted at any suitable location on the flexible supply structure 23.

Hereinabove, a flexible supply structure 23 is shown and described with respect to a first movable object 20 movably supported on a second movable object 21, in particular in a positioning module of a lithographic apparatus. The same flexible supply structure may also be used in combination with any other movable object to exchange supplies between the movable object and another object in order to improve the support of the flexible supply structure by using repulsing magnets to exert a force, for example a lifting force, on the flexible supply structure. The other object may be a movable or a stationary object.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.
Clause 1. A cable slab for connecting a first movable object with a second object.
   wherein the cable slab comprises a first permanent magnet having a first magnetic field orientation,
   wherein the cable slab is arranged to be at least partially supported by a support comprising a second magnet having a second magnetic field orientation such that the first permanent magnet and the second magnet are repulsing when the first permanent magnet and the second magnet are facing each other to exert a force on the cable slab, and
   wherein the cable slab comprises one or more clamp brackets, each clamping one or more supply hoses and/or supply cables, wherein the first permanent magnet is arranged in or on one of the one or more clamp brackets.
Clause 2. The cable slab of clause 1, wherein the force is a lifting force.
Clause 3. The cable slab of any of clause 1 or 2, wherein the cable slab is designed to be arranged in a C-shape having a lower part, a middle part and an upper part, wherein at least the lower part comprises the first permanent magnet.
Clause 4. The cable slab of any of the clauses 1-3, wherein the first permanent magnet and the second magnet are designed to support the cable slab in a floating state.
Clause 5. The cable slab of any of the clauses 1-4, wherein the cable slab comprises multiple first permanent magnets having a first magnetic field orientation, each first permanent magnet being associated with one of multiple second magnets magnet arranged in or on the support and having a second magnetic field orientation such that each first permanent magnet and associated second magnet are repulsing when the respective first permanent magnet and the respective second magnet are facing each other to exert a lifting force on the cable slab.
Clause 6. The cable slab of clause 5, wherein the cable slab comprises multiple clamp brackets each clamping one or more supply hoses and/or supply cables, wherein two or more clamping elements are provided with one or more first permanent magnets.
Clause 7. A positioning module comprising:
   a first movable object;
   a second object;
   the cable slab according to any of the preceding clauses, wherein a first end of the cable slab is connected to the first object and a second end of the cable slab is connected to the second object; and
   a support, wherein the support comprises a second magnet having a second magnetic field orientation such that the first permanent magnet and the second magnet are repulsing when the first permanent magnet and the second magnet are facing each other to exert a force on the cable slab.
Clause 8. The positioning module of clause 7, wherein the force is a lifting force.
Clause 9. The positioning module of clause 7 or 8, wherein the cable slab comprises one or more supply hoses and/or supply cables, wherein the support is arranged to support the cable slab without mechanical contact between the support and the one or more supply hoses and/or supply cables.
Clause 10. The positioning module of any of the clauses 7-9, wherein the first permanent magnet and the second magnet are designed to support the cable slab in a floating state.
Clause 11. The positioning module of any of the clauses 7-10, wherein a main axis of the second magnetic field orientation is arranged vertically.
Clause 12. The positioning module of any of the clauses 7-11, wherein the cable slab is arranged in a C-shape having a lower part, a middle part and an upper part, wherein at least the lower part is supported by the support.
Clause 13. The positioning module of any of the clauses 7-14, wherein the cable slab comprises multiple first permanent magnets having a first magnetic field orientation, wherein the support comprises multiple second magnets having a second magnetic field orientation, wherein each first permanent magnet is associated with one of the second magnets such that each first permanent magnet and associated second magnet are repulsing when the respective first permanent magnet and the respective second magnet are facing each other to exert a lifting force on the cable slab.
Clause 14. The positioning module of any of the clauses 7-13, wherein the first movable object is supported by the second object, wherein the first movable object is movable in a first horizontal direction and the second object is movable in a second horizontal direction, wherein the first horizontal direction and the horizontal second direction are non-parallel.
Clause 15. A lithographic apparatus comprising the positioning module of any of the clauses 8-14.

1-18. (canceled)

19. A cable slab comprising:
a first permanent magnet having a first magnetic field orientation;
a support comprising a second magnet having a second magnetic field orientation;
one or more supply hoses and/or supply cables; and
one or more clamp brackets each clamping the one or more supply hoses and/or supply cables,
wherein the cable slab is arranged to be at least partially supported by the support such that the first permanent magnet and the second magnet are repulsing in response to the first permanent magnet and the second magnet facing each other to exert a force on the cable slab, and
wherein the first permanent magnet is arranged in or on one of the one or more clamp brackets.

20. The cable slab of claim 19, wherein the force is a lifting force.

21. The cable slab of claim 19, wherein:
the cable slab is designed to be arranged in a C-shape having a lower part, a middle part and an upper part, and
at least the lower part comprises the first permanent magnet.

22. The cable slab of claim 19, wherein the first permanent magnet and the second magnet are designed to support the cable slab in a floating state.

23. The cable slab of claim 19, wherein the cable slab comprises:
multiple ones of the first permanent magnets having respective first magnetic field orientations, each of the multiple ones of the first permanent magnets being associated with one of multiple ones of the second magnets arranged in or on the support and having respective second magnetic field orientations,
wherein each of the multiple ones of the first permanent magnets and associated multiple ones of the second magnet are repulsing in response to the respective first permanent magnet and the respective second magnet facing each other to exert a lifting force on the cable slab.

24. The cable slab of claim 19, wherein:
the one or more clamp brackets each clamp the one or more supply hoses and/or supply cables, and
two or more clamping elements are provided with one or more of the first permanent magnet.

25. A positioning module comprising:
a first movable object;
a second object; and
the cable slab of claim 19;
wherein a first end of the cable slab is connected to the first moveable object and a second end of the cable slab is connected to the second object.

26. The positioning module of claim 25, wherein the force is a lifting force.

27. The positioning module of claim 25, wherein the support is arranged to support the cable slab without mechanical contact between the support and the one or more supply hoses and/or supply cables.

28. The positioning module of claim 25, wherein the first permanent magnet and the second magnet are designed to support the cable slab in a floating state.

29. The positioning module of claim 25, wherein a main axis of the second magnetic field orientation is arranged vertically.

30. The positioning module of claim 25, wherein the cable slab is arranged in a C-shape having a lower part, a middle part and an upper part, such that at least the lower part is supported by the support.

31. The positioning module of claim 25, wherein:
the cable slab comprises multiple ones of the first permanent magnets having first magnetic field orientations,
the support comprises multiple ones of the second magnets having second magnetic field orientations,
each of the multiple ones of the first permanent magnets is associated with one of the multiple ones of the second magnets such that each first permanent magnet and associated second magnet are repulsing in response to the respective first permanent magnet and the respective second magnet facing each other to exert a lifting force on the cable slab.

32. The positioning module of claim 25, wherein:
the first movable object is supported by the second object,
the first movable object is movable in a first horizontal direction and the second object is movable in a second horizontal direction, and
the first horizontal direction and the horizontal second direction are non-parallel.

33. A lithographic apparatus comprising:
a positioning module comprising:
a first movable object;
a second object; and
the cable slab of claim 19;
wherein a first end of the cable slab is connected to the first moveable object and a second end of the cable slab is connected to the second object.
